(19) United States
(12) Patent Application Publication
(10) Pub. No.: US 2009/0308442 A1
(43) Pub. Date: Dec. 17, 2009

(54) NANOSTRUCTURE ENABLED SOLAR CELL ELECTRODE PASSIVATION VIA ATOMIC LAYER DEPOSITION

(75) Inventor: Yue Liu, Plymouth, MN (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: Honeywell International Inc.

(21) Appl. No.: 12/138,114

(22) Filed: Jun. 12, 2008

(51) Int. Cl. H01L 31/00; H01L 31/18

(52) U.S. Cl. 136/256; 438/57; 257/E31.11

(57) ABSTRACT

A system and method for reducing charge recombination within nanostructure enabled solar cells. A nanostructure enabled solar cell includes a nanoporous electron conductor and a hole conductor. The surface of the nanoporous electron conductor includes a sensitizer of nanoparticles, such as quantum dots and also a thin and conformal passivation layer that can be selectively coated onto the electron conductor surface. The passivation layer coats the electron conductor surface without covering the surface of the nanoparticles.

### TECHNICAL FIELD

Embodiments are generally related to photovoltaic solar cell technology, specifically nanostructure enabled solar cells. Embodiments are also related to the field of atomic layer deposition.

### BACKGROUND OF THE INVENTION

Increasing energy prices, reduction in non-renewable energy resources and an increased awareness of global warming have heightened the importance of developing cost effective renewable energy. Significant efforts are underway around the world to develop cost effective solar cells to harvest solar energy. A major effort is also underway to increase solar cell efficiency, thereby producing significantly more energy per solar cell device.

The use of photovoltaic cells for the direct conversion of solar radiation into electrical energy is well known. When photons strike the solar cell, they create an electron-hole pair whereby the photons bump electrons out of the atoms and make them available to flow through the device. Generally, the photovoltaic cell comprises a substrate of semi-conductive material having a p-n junction defined therein. In the planar silicon cell the p-n junction is formed near a surface of the substrate which receives impinging radiation. Only photons having at least a minimum energy level higher than that of the semiconductor bandgap can be absorbed and generate an electron-hole pair in the semiconductor pair. Photons having less energy are not absorbed, and the excess energy of photons higher than that of the semiconductor bandgap simply creates heat. These and other losses limit the efficiency of silicon photovoltaic cells in directly converting solar energy to electricity to less than 30% under normal solar illumination.

A nanostructure enable solar cell (NESC) is a solar cell based on certain transparent electrode with a coating of nanoparticles. Nanoparticles are very efficient in absorbing light and generating electron-hole pairs when exposed to sunlight. Nanoparticles may include quantum dots (QD), nanotubes, and nanowires, among others, in an NESC. A photon with sufficient energy will dislodge an electron from an atom in a quantum dot, generating an electron-hole pair. The quantum dots occupy such a small space that the electrons and holes are boxed-in, or quantum-confined. Because of this confinement, an electron or hole liberated by the photon is restricted to a set of energy levels that are dependent on the size of the quantum dot. The smaller the dot, the greater the band-gap.

An example of a nanostructure enabled solar cell is disclosed in U.S. Patent Publication No. 2007/0025139. U.S. Patent Publication No. 2007/0025139 discloses a nanostructure enabled solar cell including a substrate having a horizontal surface and an electron conductor layer on the substrate. The nanostructure enabled solar cell further includes a plurality of vertical surfaces substantially perpendicular to the horizontal surface. Light-harvesting rods are electrically coupled to the vertical surface of the electrode. U.S. Patent Publication No. 2007/0025139 is incorporated herein by reference in its entirety.

In a nanostructure enabled solar cell (NESC), one of the key issues that limits the performance is the carrier loss due to the charge recombination occurring at the surface of the nanoporous electron conductor (EC) and the hole conductor (HC). Recombination is a loss process in which an electron, which has been excited from the valence band to the conduction band of a semiconductor, falls back into an empty state in the valence band, which is known as a hole. The imperfection of the electron conductor (EC) surface forms certain trap states or surface states through which the electron in the electron conductor can recombine with a hole in the hole conductor (HC). Charges that recombine do not produce any photocurrent and, hence, do not contribute towards solar cell efficiency. Such recombination loss is potentially significant because of the large surface area that exists between the two interpenetrated porous components. The design of such a device would call for a maximum amount of the surface of the porous electron conductor to be covered by a desired solar absorber, such as dye molecules (as in the case of a dye-sensitized solar cell or DSSC) or quantum dots (in the case of a nanostructure enable solar cell or NESC).

A system and/or a method which would result in a reduction in the recombination of the electrons in a nanostructure enabled solar cell (NESC) would significantly contribute towards the solar cell efficiency.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved photovoltaic solar cell.

It is another aspect of the present invention to provide for an increased efficiency nanostructure enabled solar cell.

It is another aspect of the present invention to provide for a method and system to reduce charge recombination within a nanostructure enabled solar cell.

The aforementioned aspects and other objectives and advantages can now be achieved as described herein. A nanostructure enabled solar cell is described herein, which includes a nanoporous electron conductor (EC) and a hole conductor (HC). The surface of the nanoporous electron conductor generally includes a sensitizer of nanoparticles and also a thin and conformal passivation layer selectively coated onto the EC surface. The passivation layer coats the EC surface without covering the surface of the nanoparticles.

In the present invention, incident photons are absorbed by the quantum dots and create electron-hole pairs (excitons). The electrons are injected into the electron conductor and the holes are injected into the hole conductor. The quantum dots are desired to cover as much surface area of the electron conductor as possible, but may not cover the entire surface area of the electron conductor, so that the electron conductor and the hole conductor are partially in contact with each other. The imperfection of the electron conductor surface forms a certain trap state or surface state through which the electrons in the electron conductor can recombine with holes in the hole conductor. The thin passivation layer between the EC and HC serves the purpose of terminating certain dangling bonds, thereby reducing the potential path for recombination and creating a barrier layer to keep the carriers in the electron conductor and the hole conductor apart.

The passivation layer may be applied to the electron conductor through atomic layer deposition (ALD), a gas phase chemical process used to make extremely thin coatings. ALD utilizes chemicals (precursors) to react with the surface in a sequential manner. The precursors are exposed to the growth surface of the EC repeatedly as the thin passivation layer is deposited.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a nanostructure enabled solar cell, which can be implemented in accordance with a preferred embodiment;

FIG. 2 illustrates a nanoporous electron conductor, which can be implemented in accordance with a preferred embodiment;

FIG. 3 illustrates a nanoporous electron conductor with quantum dots attached, but not fully covering its surface in accordance with a preferred embodiment;

FIG. 4 illustrates a nanoporous electron conductor with quantum dots and the selective passivation layer, in accordance with a preferred embodiment;

FIG. 5 illustrates a nanoporous electron conductor and a hole conductor with the selective passivation layer and quantum dots between the conductors, in accordance with a preferred embodiment; and

FIG. 6 illustrates a flowchart of the process steps for producing a nanostructure enabled solar cell electrode passivation via atomic layer deposition, in accordance with a preferred embodiment.

### DETAILED DESCRIPTION

The particular values and configurations discussed in these non-limiting examples can be varied and are cited merely to illustrate at least one embodiment and are not intended to limit the scope thereof.

The present invention includes a nanostructure enabled solar cell, which further includes a nanoporous electron conductor (EC) and a hole conductor (HC). The surface of the nanoporous electron conductor includes a sensitizer of nanoparticles, such as quantum dots (QD) and also a thin and conformal passivation layer selectively coated onto the EC surface. The passivation layer coats the EC surface without covering the surface of the nanoparticles.

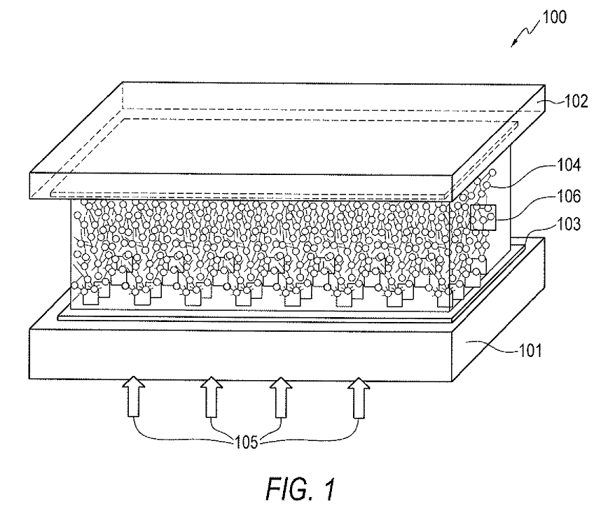

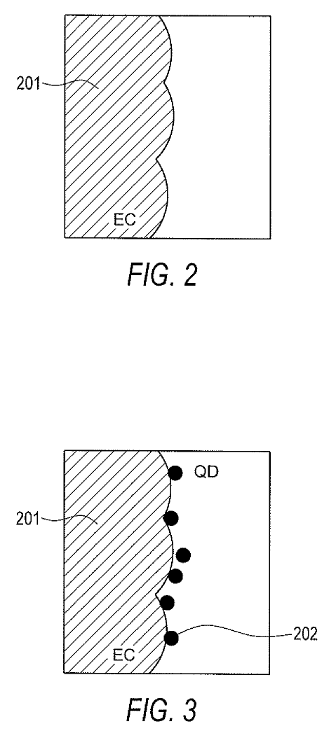

FIG. 1 illustrates an exemplary nanostructure enabled solar cell 100, in accordance with a preferred embodiment. As shown in FIG. 1, NESC 100 includes a flexible or rigid transparent substrate 101, wherein solar energy, as indicated by arrow 105, enters the NESC 100. The NESC 100 further includes anode 102 and cathode 103 separated by light harvesting rods 104. Further detail of light harvesting rods 104, as indicated by detail area 106, is shown in FIGS. 2-5.

FIGS. 2-5 illustrate a close-up detail of the light harvesting rods 104 of FIG. 1 and illustrate sequential steps in forming an NESC with a nanoporous electrode passivation via ALD in accordance with a preferred embodiment. FIG. 2 illustrates a nanoporous electron conductor 201 of NESC 100. The nanoporous EC 201 can be several microns thick with a pore size of less than 100 nm. The surface roughness of the EC 201 factors about 50-100× per micron of thickness of the EC 201.

FIG. 3 illustrates a schematic diagram of a nanoporous electron conductor covered with a sensitizer or a solar absorber such as quantum dot(s) 202 attached. A quantum dot is generally a semiconductor whose excitons are confined in all three spatial directions. As a result, such quantum dots possess properties that are similar to those between bulk semiconductors and discrete molecules. Quantum dots 202 may be provided, for example, as lead selenide (PbSe) or any other suitable semiconductor and can produce at least one or as many as seven excitons from one high energy photon of sunlight. It is desirable to attach as many quantum dots 202 and to cover as high a percentage of the given nanoporous electron conductor 201 surface area as possible. It is expected, however, that a certain percentage of the nanoporous electron conductor 201 surface area will not be covered by the quantum dots 202.

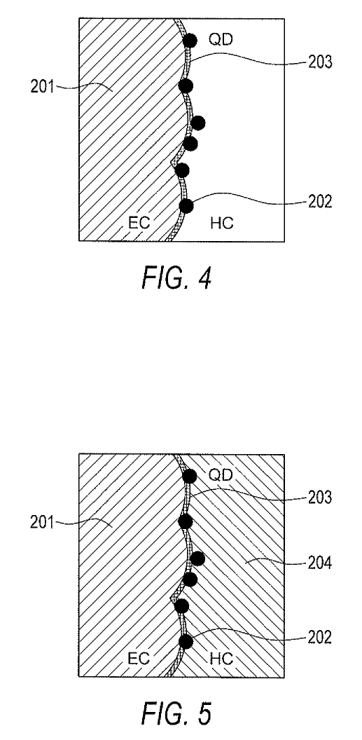

FIG. 4 illustrates a nanoporous electron conductor 201 with quantum dots 202 and a selective passivation layer 203. The passivation layer 203 is a thin layer applied to the EC 201 such that the passivation layer 203 does not clog the pores of the nanoporous EC 201. The passivation layer 203 should be thin such that the thickness is in the nanometer thickness range (˜nm). Additionally, the passivation layer 203 should be a conformal and continuous layer on the nanoporous EC 201. A conformal layer, as defined herein, is a morphologically uneven interface with another body which has a thickness that is the same, or nearly the same, everywhere along the interface. The passivation layer 203 should be selective to the EC surface such that the passivation layer 203 should coat the EC 201 surface without covering the quantum dots 202.

One method which may produce the passivation layer 203 of FIG. 4 is atomic layer deposition (ALD). ALD is a self-limiting, sequential surface chemistry process which allows deposition of a conformal thin film. ALD can achieve atomic scale deposition control. Atomic layer control of the film grown can be obtained as fine as ˜0.1 angstroms per monolayer by keeping the precursors separate throughout the coating process. ALD has unique advantages for the deposition of passivation layer 203 in that it can grow films that are conformal, pin-hole free, and are chemically bonded to the surface of the EC 201. Utilizing ALD allows the passivation layer 203 to be thin and conformal inside of deep trenches, porous substrates and around particles without covering the sensitizer, such as quantum dots 203. The passivation layer 203 may be composed of a dielectric oxide or any other suitable compound such as an insulating or a semiconductor composite.

FIG. 5 illustrates a schematic diagram of a nanoporous electron conductor 201 and a hole conductor 204 with the selective passivation layer 203 and the quantum dots 202 located between EC/HC conductors. As indicated by the configuration depicted in FIG. 5, the passivation layer 203 generally acts as a barrier between the EC 201 and the HC 204. This barrier of the passivation layer 203 serves the purpose of terminating dangling bonds, which cuts down or reduces the potential paths for charge recombination. Such a configuration also functions to provide a physical barrier that maintains the charges in the EC 201 and the holes in the HC 204 (e.g., electron-hole pairs) apart from one another.

In a nanostructure enabled solar cell (NESC), one of the key issues that limit the performance is the carrier loss due to the charge recombination occurring at the surface of the EC 201 and the HC 204. Charges that recombine do not produce any photocurrent and, hence, do not contribute towards solar cell efficiency. Such a recombination loss can be potentially significant because of the potentially large surface area that exists, which may not be covered by quantum dots 202 between the two interpenetrated porous components. The design of an NESC 100 preferably calls for a maximum amount of the surface of the EC 201 to be covered by the sensitizer as quantum dot(s) 202. Even with a substantial portion of the EC 201 covered with the quantum dot(s) 203, there is an appreciable portion wherein the EC 201 would be exposed directly to the HC 204 if it were not for the passivation layer 203. By creating such a passivation layer 203 between the EC 201 and HC 204, charge recombination is significantly reduced, which in turn increases the efficiency of the nanostructure enabled solar cell.

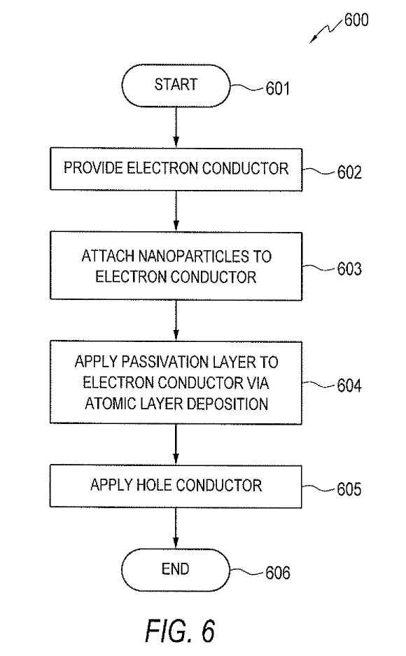

FIG. 6 illustrates a high-level flowchart of operations depicting a method 600 for producing a nanostructure enabled solar cell electrode passivation via atomic layer deposition, in accordance with a preferred embodiment of the present invention. The process is initiated as depicted at block 601. An electron conductor can be provided on top of a substrate with a transparent conductive layer as depicted at block 602. A layer of nanoparticles (e.g., quantum dots, nanotubes, nanowires or other suitable nanoparticles) can be attached to the electron conductor surface, as shown at block 603. Thereafter, atomic layer deposition can be utilized to apply a thin passivation layer to the electron conductor as illustrated at block 604. This passivation layer should be conformal and selective to the electron conductor such that it does not cover the nanoparticles. The hole conductor is thereafter applied, as described at block 605, so that the passivation layer is located generally between the EC and the HC, thereby reducing the charge recombination and a back contact layer is added to the HC. The method 600 is then completed as illustrated at block 606.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A photovoltaic solar cell apparatus, comprising:
an electron conductor;
a hole conductor; and
a barrier disposed between said electron conductor and said hole conductor to thereby reduce charge recombination in said photovoltaic solar cell.

2. The apparatus of claim 1 wherein a sensitizer is disposed on a surface of said electron conductor.

3. The apparatus of claim 1 wherein said barrier comprises a passivation layer.

4. The apparatus of claim 2 wherein said sensitizer comprises a plurality of nanoparticles.

5. The apparatus of claim 3 wherein said nanoparticles comprise quantum dots.

6. The apparatus of claim 4 wherein:
said barrier comprises a passivation layer that is selective to said electron conductor surface such that said passivation layer is conformal and coats only said electron conductor; and
said passivation layer comprises a material selected from at least one of the following materials:
an insulating composite; and
a semiconductor composite.

7. The apparatus of claim 6 wherein said passivation layer comprises dielectric oxide.

8. A nanostructure enabled solar cell apparatus, comprising:
a nanoporous electron conductor;
a hole conductor; and
a barrier disposed between said nanoporous electron conductor and said hole conductor to thereby reduce charge recombination in said nanostructure enabled solar cell.

9. The apparatus of claim 8 wherein said barrier comprises a thin conformal passivation layer.

10. The apparatus of claim 8 further comprising a plurality of nanoparticles attached to said nanoporous electron conductor.

11. The apparatus of claim 10 wherein said barrier comprises a thin conformal passivation layer that comprises a material selected from at least one of the following materials:
an insulating composite; and
a semiconductor composite.

12. The apparatus of claim 11 wherein said thin conformal passivation layer comprises dielectric oxide.

13. The apparatus of claim 8 further comprising a sensitizer comprising a plurality of nanoparticles attached to said nanoporous electron conductor.

14. The apparatus of claim 13 wherein said barrier comprises a thin conformal passivation layer selective to said nanoporous electron conductor.

15. A method of forming a nanostructure enabled solar cell comprising the steps of:
providing a nanoporous electron conductor;
attaching nanoparticles to said nanoporous electron conductor;
applying a thin passivation layer to said nanoporous electron conductor utilizing atomic layer deposition wherein said passivation layer comprises either an insulating composite or a semiconductor composite;
applying a hole conductor to said nanoporous electron conductor such that said thin passivation layer is between said electron conductor and said hole conductor to thereby reduce charge recombination in said nanostructure enabled solar cell.

16. The method of claim 15 further comprising configuring said thin passivation layer to be selective to said nanoporous electron conductor such that said thin passivation layer coats only said nanoporous electron conductor.

17. The method of claim 15 further comprising configuring said nanoparticles to comprise quantum dots.

18. The method of claim 15 further comprising configuring said thin passivation layer as a conformal layer.

19. The method of claim 15 further comprising configuring said passivation layer from a dielectric oxide material.

20. The method of claim 17 further comprising configuring said thin passivation layer to be selective to said nanoporous electron conductor such that said thin passivation layer coats said nanoporous electron conductor only and wherein said thin passivation layer is conformal.
